(19) United States
(12) Patent Application Publication
(10) Pub. No.: US 2018/0019143 A1
(43) Pub. Date: Jan. 18, 2018

(54) BIN INSERT FOR BINNING OF LIGHT EMITTING DEVICES, BINNING ARRANGEMENT FOR BINNING OF LIGHT EMITTING DEVICES, AND USE OF A BINNING ARRANGEMENT FOR BINNING OF LIGHT EMITTING DEVICES

(71) Applicant: OSRAM Opto Semiconductors GmbH, Regensburg (DE)

(72) Inventors: Aylwin NG, Bayan Lepas (MY); Kok San TEOH, Ayer Itam (MY)

(73) Assignee: OSRAM Opto Semiconductors GmbH, Regensburg (DE)

(21) Appl. No.: 15/554,705

(22) PCT Filed: Mar. 4, 2015
(86) PCT No.: PCT/EP2015/054517

§ 371 Date: Aug. 30, 2017

(51) Int. Cl. H01L 21/67; B07C 5/38; B65B 39/00; H01L 33/00

(52) U.S. Cl. CPC H01L 21/67271; B65B 39/007; B07C 5/38; H01L 33/00

(57) ABSTRACT

A bin insert for binning of light emitting devices comprises a hollow structural section (1). The hollow structural section (1) further comprises a top opening (13) and a bottom opening (14) at a top and a bottom end (11, 12) of the hollow structural section (1), respectively. A wall (15) extends along a main axis (10) between the top opening (13) and the bottom opening (14). Parallel segments (16) in the wall extend parallel with respect to the main axis (10). Inclined segments (17) in the wall (15) extend under a tilted angle and towards the main axis (10). The parallel segments (16) and the inclined segments (17) are arranged such as to confine an angulated falling path in the hollow structural section (1).

This invention relates to a bin insert for binning of light emitting devices, binning arrangement for binning of light emitting devices, and use of a binning arrangement for binning of light emitting devices.

Light emitting devices such as light emitting diodes (LEDs) are produced in large quantities. Even for the same batch, however, LEDs vary in their characteristic parameters such as color, flux and forward voltage. The differences can be significant. In order to account for these deviations LEDs are measured and grouped into bins of similar properties. This process of collecting LEDs of similar properties is called binning. A particular bin may contain LEDs, which emit light within a determined range of wavelengths, range of flux values and range of forward voltage that can be applied safely to the LEDs.

A bin is a container into which the LEDs are collected and dropped by means of an automated binning machine, for example. However, common binning machines introduce a problem known as LED glass window chipping. The problem is caused by devices at the base of the bin getting hit directly and by other falling devices which are being dropped into the bins by the machine. This may lead to several defects like high yield losses due to window chipping. Chipping in the middle of the glass window, directly on top of the LED chip may also affect the radiation pattern of the particular device. Furthermore, the bins are typically made of aluminum and may get worn out due to frequent use. Worn out aluminum bins would release aluminum particles, which, in turn, may contaminate the devices in the bins and the brightness of the devices may be reduced, for example. Replacing worn out aluminum bins in order to avoid contamination goes along with high costs when replacing bins in large quantities.

There have been attempts to minimize the problem by avoiding purging of devices into the bins at high speed with compressed air in order to reduce the speed of devices falling down to the base of the bin. The devices are dropped by gravity into the bins from a pickup head of the machine.

However, the glass window chipping problem caused by the machine-aided binning process could not be solved this way as the speed of devices falling down into the bin by virtue of gravity could not be controlled. In fact, it was not yet possible to avoid the devices at the base of the bins from getting hit directly from falling devices from the top.

It is an object of the present invention to provide a bin insert for binning of light emitting devices, a binning arrangement for binning of light emitting devices and use of said binning arrangement for binning of light emitting devices in order to avoid glass window chipping of light emitting devices during binning.

According to the principles presented, this object is achieved by the subject matter of the independent claims. Further developments and embodiments are described in the dependent claims.

A bin insert for binning of light emitting devices according to the present principle comprises a hollow structural section. The hollow structural section comprises a top opening and a bottom opening at a top and a bottom end, respectively. A wall of the hollow structural section extends along a main axis between the top opening and the bottom opening. The wall comprises parallel segments and inclined segments. The parallel segments in the wall extend parallel with respect to the main axis. The inclined segments in the wall extend under a tilted angle and extend towards the main axis. The parallel segments and the inclined segments are arranged such as to confine an angulated falling path in the hollow structural section.

The bin insert can be used for binning of light emitting devices such as light emitting diodes (LED). Typically, the bin insert is inserted into a bin, such as an aluminum bin. Basically, the bin constitutes a container to collect light emitting devices of certain common characteristics, for example. Typically the bin insert is standing upright with its top end and bottom end facing up and down, respectively. This way a light emitting device inserted into the top opening can fall along the angulated falling path towards the bottom end by virtue of gravity. The inclined segments constitute inclined planes or baffles in the wall. These planes or baffles have a certain area onto which a light emitting device can move on. The inclined segments constitute fall breakers and deflect the light emitting device from falling down the insert bin in a straight path. The angulated falling path provides at least one such deflection so that the light emitting device is slowed down at least once when falling down the angulated falling path.

Thus, instead of purging light emitting devices directly into the bins, the devices are dropped through the bin insert having the fall breakers formed by the inclined segments. The inclined segments will slow down the falling speed of the devices after being dropped into the inserted by a binning machine. The light emitting devices will accumulate at the bottom end of the bin insert. As the bottom of the bin insert is open the light emitting devices will stay in the bin when the bin inside is removed from the bin.

Preferably, there is more than just a single inclined segment in the wall. This way there will be more than a single deflection in the angulated falling path. The angulated falling path may be angulated at multiple points along the main axis of the hollow structural section.

The bin insert minimizes the impact of falling devices and prevents falling devices from landing directly on other devices on the base of the bin. The bin insert may significantly reduce or even eliminate glass window chipping caused by the dropping of devices into the bins. The bin inserts also reduce yield losses caused by glass window chipping and improve productivity of production in general. There is no need to replace the insert often as it can be made of material which is more resistant against wearing and tearing as an aluminum bin, for example. The choice of material can also reduce potential contamination of the devices. The bin inserts can be more easily cleaned for reuse and offer a long life span. The possibility of reusing the bin inserts more often lowers replacement costs compared to aluminum bins only. The use of inserts also renders quite easy the clearing of a bin after removal of the insert.

The parallel and inclined segments in the wall can be characterized by a tilting angle. The tilting angle denotes the deviation from the main axis (in terms of degrees). For example, the tilting angle for the parallel segments is 0° by definition. The tilting angle of the inclined segments can range from values greater than 0° up to 90°. In the latter case the inclined segments is perpendicular to the main axis. However, the choice of tilting angles for the inclined segments is restricted to values that allow light emitting devices to fall down the bin insert without getting stuck on the way. For example, the tilting angle for the inclined segments is 45° or higher. The actual choice depends on different factors like the material of the bin insert or speed of falling light emitting devices. The tilting angle can be the same for most or all inclined segments. For easier reference the main axis can be a center axis of the bin insert.

According to another aspect the hollow structural section is confined by a circular, a rectangular, or a square shaped cross-section. Preferably, the parallel segments in the wall have a circular, a rectangular, or a square shaped cross-section. The latter cross-section can essentially be the same for all parallel segments such that a bin having essentially the same cross-section may enclose the bin insert and the bin insert can be inserted into the bin.

According to another aspect the top opening and the bottom opening extend over the whole cross-section of the hollow structural section.

This way a full opening at the top and bottom end can be used to insert or exit light emitting devices from the bin insert. Furthermore, large openings support easy cleaning for later reuse of the bin insert in case the inner surface is covered by particles which may contaminate the light emitting devices.

According to another aspect the parallel segments and the inclined segments confining the angulated falling path in the hollow structural section are arranged such that the angulated following path connects the top opening with the bottom opening of the hollow structural section.

During binning light emitting devices are inserted into the bin insert and by virtue of gravity fall from the top to the bottom end of the hollow structural section. The angulated falling path connecting the top to the bottom end provides a continuous path for the light emitting devices so the risk of getting stuck is minimized.

According to another aspect the bin insert comprises at least two inclined segments forming a pair of inclined segments. In fact, the two inclined segments of the pair are tilted with respect to each other so as to form a wedge in the wall.

The inclined segments constitute inclined planes or baffles in the wall. These planes or baffles have a certain area onto which a light emitting device can move on. The wedge can be adjusted to provide a certain angle of inclination. This angle of inclination is defined by the tilting angles of the two inclined segments constituting the pair, respectively. The angle of inclination is chosen to allow light emitting devices to fall from the top end of the hollow structural section down the bin insert without getting stuck.

According to another aspect the bin insert comprises at least one further pair of inclined segments. The two further inclined segments of the at least one further pair are tilted with respect to each other so as to form a further wedge in the wall. The angle of inclination of the at least one further pair of inclined segments is chosen to allow light emitting devices to fall from the top end of the hollow structural section down the bin insert without getting stuck.

In general, the number of inclined segments is not restricted and can be chosen according to a given application or in view of a desired slow down of falling speed. Preferably, the bin insert comprises two pairs of inclined segments arranged to form the wedge and the at least one further wedge. Both wedges are arranged with respect to each other so as to allow light emitting devices to fall from the top end of the hollow structural section down the bin insert without getting stuck.

According to another aspect the wedge and the at least one further wedge are arranged with respect to each other such that the angulated falling path in the hollow structural section comprises a zigzag course. The zigzag course connects the top and with the bottom opening of the hollow structural section.

Instead of allowing light emitting devices to drop down the bin insert in a straight line onto other devices at the bottom, the bin insert will ensure that of the devices travel down in a following the zigzag course being deflected by means of the inclined segments multiple times before finally reaching the bottom. The final dropping point is also away from the final resting point of the light emitting devices. Therefore, the devices would not drop directly on other devices on the bin, for example.

According to another aspect the bin insert comprises a receiving portion having a top side connected to the wedge or to the at least one further wedge. The receiving portion has also a bottom side comprising the bottom opening of the hollow structural section.

The receiving portion is used to collect light emitting devices after they have been falling down the bin insert along the angulated falling path confined by the parallel and inclined segments in the wall, e.g. the wedge and the at least the one further wedge. Preferably, in the receiving portion of the hollow structural section the wall comprises only parallel segments. A level of the receiving portion determines the amount of light emitting devices that can be collected using a single bin insert.

Preferably, the tilting angle of the inclined segment closest to the top side of the receiving portion is perpendicular with respect to the main axis in order to maximize the level of devices that can be collected using the bin insert. The maximum quantity of light emitting devices in the insert bin would be limited according to the size of the particular light emitting devices so that it would not be exceeding the level of the receiving portion. This would prevent large quantities of devices get from getting stuck in the following path.

According to another aspect the bottom opening of the hollow structural section is slanted with respect to the main axis. The slanted bottom opening may correspond to a slanted base of a bin into which the being insert is to be inserted.

This way light emitting devices falling down the falling path could hit the slanted base at a certain point and then move down along the base because of its inclination to a lower part until finally coming to a stop. This way the dropping point is shifted from the final resting point of the devices and the devices would not drop directly on the devices on the bin base. Furthermore, the bin insert can be cleared out from light emitting device without any obstacles.

According to another aspect the hollow structural section is made of an at least semitransparent plastic. In particular, the hollow structural section can be made of semitransparent electrostatic sensitive device (ESD) plastic.

When using a plastic or ESD plastic as material for the bin insert the amount of wearing and tearing can be reduced. As the insert bin is not only covered by ESD coating, there would be no ESD concern due to wear and tear after using the same insert for longer time. A semitransparent plastic provides relatively clear visibility of the content inside the plastic insert, making it easier for operators to ensure that it is completely cleared of stray units before reusing it for the next cycle.

According to another aspect of the hollow structural section comprises a molded plastic. The costs of replacing a molded plastic in insert can be far cheaper than replacing fabricated aluminum bins.

A binning arrangement for binning of light emitting devices, in particular for binning of light emitting diodes comprises a bin insert according to the principles presented above. Furthermore, the binning arrangement comprises at least one bin designed for receiving the bin insert.

The binning arrangement can be used for binning of light emitting devices such as light emitting diodes (LED). Typically, the bin insert is inserted into a bin, such as an aluminum bin and is standing upright with its top end and bottom end facing up and down, respectively. This way a light emitting device inserted into the top opening can fall along the angulated falling path towards the bottom end by virtue of gravity. The inclined segments constitute inclined planes or baffles in the wall. These planes or baffles have a certain area onto which a light emitting device can move on. The inclined segments constitute fall breakers and deflect the light emitting device from falling down the insert bin in a straight path. The angulated falling path provides at least one such deflection so that the light emitting device is slowed down at least once when falling down the angulated falling path.

Thus, instead of purging light emitting devices directly into the bins, the devices are dropped through the bin insert having the fall breakers formed by the inclined segments. The inclined segments will slow down the falling speed of the devices after being dropped into the inserted by a binning machine. The light emitting devices will accumulate at the bottom end of the bin insert. As the bottom of the bin insert is open the light emitting devices will stay in the bin when the bin inside is removed from the bin.

The bin insert minimizes the impact of falling devices and prevents falling devices from landing directly on other devices on the base of the bin. The bin insert may significantly reduce or even eliminate glass window chipping caused by the dropping of devices into the bins. The bin inserts also reduce yield losses caused by glass window chipping and improve productivity of production in general. There is no need to replace the insert often as it can be made of material which is more resistant against wearing and tearing as an aluminum bin, for example. The choice of material can also reduce potential contamination of the devices. The bin inserts can be more easily cleaned for reuse and offer a long life span. The possibility of reusing the bin inserts more often lowers replacement costs compared to aluminum bins only. The use of inserts also renders quite easy the clearing of a bin after removal of the insert.

According to another aspect the bin insert is designed to fit into the at least one bin.

According to another aspect of a slanted base of the bin corresponds to the slanted to bottom opening of the bin insert.

This way light emitting devices falling down the falling path could hit the slanted base at a certain point and then move down along the base because of its inclination to a lower part until finally coming to a stop. This way the dropping point is shifted from the final resting point of the devices and the devices would not drop directly on the devices on the bin base. Furthermore, the bin insert can be cleared out from light emitting device without any obstacles.

In the following, the principle presented above is described in further detail with respect to drawings, in which exemplary embodiments are presented.

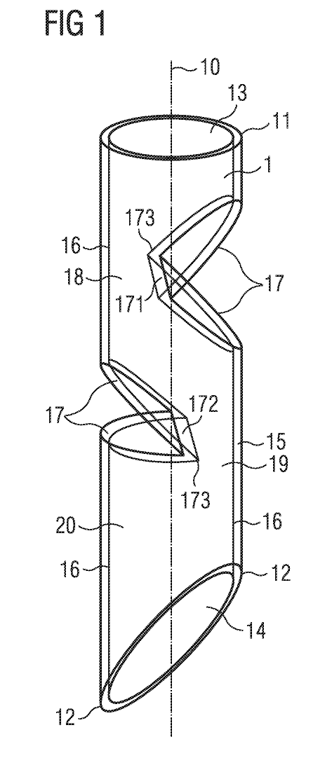

FIG. 1 shows an exemplary embodiment of a bin insert,

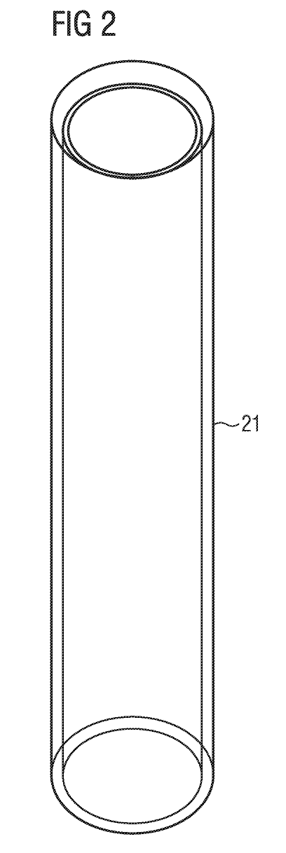

FIG. 2 shows an exemplary embodiment of a bin insert inserted into an aluminum bin,

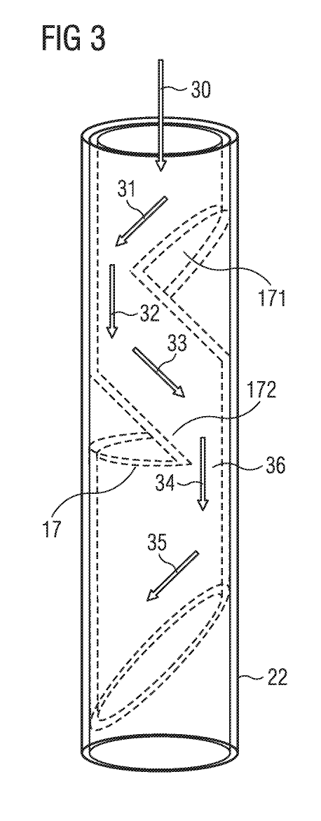

FIG. 3 shows another exemplary embodiment of a bin insert inserted into an aluminum bin, and

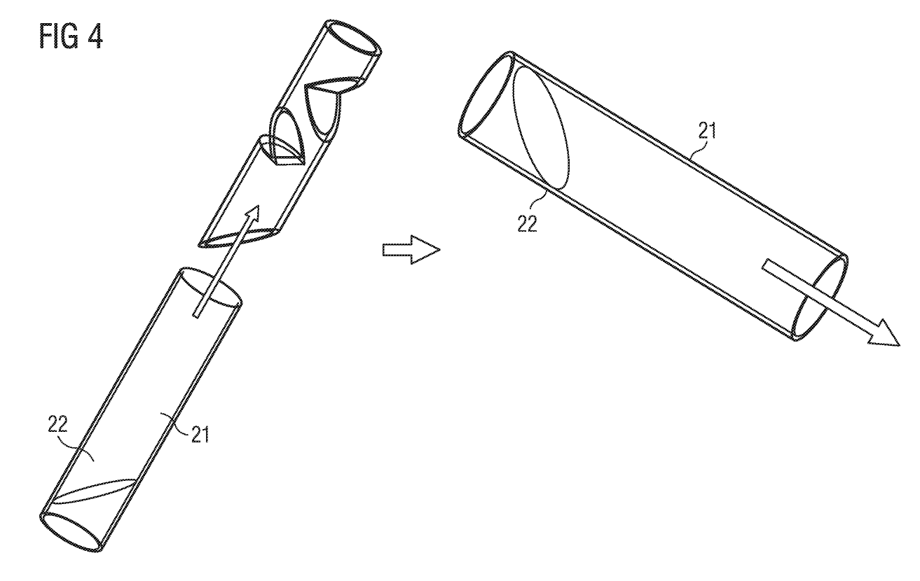

FIG. 4 shows an exemplary binning arrangement.

FIG. 1 shows an exemplary embodiment of a bin insert. The bin insert comprises a hollow structural section 1 having a main axis 10 (depicted as a main center axis in the drawing). Basically the hollow structural section 1 is a conduit- or pipe like structure and can essentially be of a circular, a rectangular or a square profile. The hollow structural section extends 1 along the main axis 10 and has a top end 11 and a bottom end 12. A top opening 13 is positioned at the top end 11 and a bottom opening 14 is positioned at the bottom end 12. Both openings 13, 14 extend over the larger part of the profile of the hollow structural section 1.

Furthermore, the hollow structural section 1 comprises a wall 12 having parallel 16 and inclined segments 17. The parallel and inclined segments 16, 17 in the wall 15 can be characterized by a tilting angle. The tilting angle denotes the deviation from the main axis 10 (in terms of degrees). For example, the tilting angle for the parallel segments 16 is 0° by definition. The tilting angle of the inclined segments 17 can range from values greater than 0° up to 90°. In the latter case the inclined segments 17 are perpendicular to the main axis.

The inclined segments 17 are arranged in pairs and form wedges 171, 172 inside the wall 15. Each inclined segment 17 forms an inclined plane having a certain area. The areas are indicated has grey areas in the drawing. The inclinded segments 17 in a pair or wedge 171, 172 are tilted with respect to each other and have a point of contact 173 where they meet.

In FIG. 1 a first and second wedge 171, 172 are depicted each comprising a first and second inclined segment 17, respectively. In this particular embodiment the first inclined segment 17 in the first wedge 171 has a tilting angle oriented towards the main axis 10. For example, this tilting angle is about 45°. Other values are possible as well. The tilting angle of the second inclined segment 17 of the first wedge 171 essentially is the same as the tilting angle of the first inclined segment 17 of the second wedge 172. This way the second inclined segment 17 in the first wedge 171 and the first inclined segment 17 in the second wedge 172 are parallel and leave open a path between them. Finally, the second inclined segment 17 in the second wedge 172 has a tilting angle of 90° making it perpendicular to the main axis 10.

The wedges 171, 172 or inclined segments 17 extend towards the main axis 10 with a certain amount. Depending on how far the wedges 171, 172 extend into the hollow structural section 1 they leave open narrow areas. In the drawing the first wedge 171 leaves open a first narrow area 18 and the second wedge 172 leaves open a second narrow area 19 in the hollow structural section 1. These narrow areas 18, 19 should be larger than light emitting devices to be binned using the bin insert. As an example, the wedges 171, 172 extend towards the main axis 10 until about one radius of the profile of the hollow structural section 1.

The bin insert is made of semitransparent ESD plastic. ESD plastics are plastics that reduce static electricity to protect electrostatic-sensitive devices (ESD), like polyethylene, for example. The lower part of the bin insert comprises a receiving section 20 which basically serves as a container. The receiving section 20 comprises the second inclined segment 17 of the second wedge 172 as an upper part. At a lower part the receiving section 20 comprises the bottom opening 14.

FIG. 2 shows an exemplary embodiment of a bin insert inserted into an aluminum bin. The bin insert of FIG. 1 can be inserted into a bin 21, preferably, an aluminum bin for use as a binning arrangement. The bin 21 has a profile similar to that of the bin insert so that the insert can be inserted into the bin without much play. Correspondingly, the bin 21 and the insert bin have similar length as well so that the insert bin can be completely inserted into the bin but also be easily removed when binning has been completed.

FIG. 3 shows another exemplary embodiment of a bin insert inserted into an aluminum bin. The drawing shows schematically how the bin insert of FIG. 1 can be inserted into the bin 21 of FIG. 2. The bin 21 has a slanted base 22 which corresponds to the bottom opening 14 of the bin insert which is also slanted with the same tilting angle. This way the bin insert fits into the bin 21 in a defined position and orientation.

The binning arrangement in FIG. 3 can be used to collect light emitting devices like light emitting diodes (LED) into the bin 21, a process called binning. The bin insert will be placed inside the bin 21 before devices are dropped into it. Typically, a binning arrangement comprises a multitude of several bins 21 and corresponding bin inserts in order to group light emitting devices into several groups.

Basically, a light emitting device is inserted into the binning arrangement via the top opening 11 of the bin insert. By virtue of gravity the light emitting device drops down the bin insert and is collected at the lower part of the receiving section 20. Thus, instead of purging devices directly into the bins 21, the devices are dropped into the bin insert.

The inclined segments 17 or wedges 171, 172 function as fall breakers and will slow down the traveling speed of a light emitting device after being dropped into the bin insert by a binning machine. Said light emitting device will follow an angulated falling path which is defined by the positions of the inclined segments 17 of wedges 171, 172. The angulated falling path is indicated by grey arrows in the drawing 30, 31, 32, 33, 34, 35. In the particular embodiment of FIG. 3 the inclined segments 17 and wedges 171, 172 ensure that the light emitting devices travel down the bin insert in a zigzag path before reaching the base of the bin. In order to assure that the angulated falling path is continuous so that the falling light emitting devices cannot get stuck on the way, the narrow areas 18, 19 between the point of contact 173 of the wedges 171, 172 and a parallel segment 16 of the wall 15 need to be chosen large enough to fit a light emitting device.

The first and second wedges 171, 172 or fall breakers reduce the falling speed of light emitting devices dropped into the bin insert and minimize the impact when they hit other devices already present at the bin base 22. The final dropping point of a light emitting device is also shifted away from the final resting point of the device at the bin base 22 because of its slanted angle. Therefore, the devices would not drop directly on and other devices on the bin base.

The second inclined segment 17 of the second wedge 172 will also function as a protection to the devices which have been accumulated at the base 22 of the bin from being hit directly and by other falling devices from the top. The maximum quantity of devices in the bin insert is limited according to the size of the receiving section so that it would not be exceeding the level indicated by reference numeral 36 in the drawing. This would prevent a larger quantity of devices from getting stuck at the narrow area 19 of the bin insert.

As the bin insert is made of semitransparent ESD plastic there would be no ESD concern due to possible surface wear and tear after using the same bin insert for some time. The semitransparent material allows for relatively good visibility of devices inside the insert, which makes it easier for operators to check and ensure that the plastic bin insert is completely empty to prevent possible mixed binning. The large opening at the bottom 14 of the plastic bin insert ensures that light emitting devices drop out of the insert smoothly after it is been taken out from the aluminum bin (see also FIG. 4). The plastic bin insert will protect the aluminum sidewall of the bin from getting hit repeatedly by the falling light emitting devices and course the anodized surface of the inner aluminum wall to wear out.

FIG. 4 shows an exemplary binning arrangement. The drawing depicts how the bin insert is removed from inside of the aluminum bin 21 in order to finalize the binning collection. To clear the bin 21, the plastic bin insert is simply pulled out from the top of the aluminum bin. The devices which remain in the aluminum bin could then be cleared easily without any obstacles.

### REFERENCE NUMERALS

1 hollow structural section
10 main axis
11 top end
12 bottom end
13 top opening
14 bottom opening
15 wall
16 parallel segment
17 inclined segment
18 narrow area
19 narrow area
20 receiving section
21 bin
22 base
31 arrow
32 arrow
33 arrow
34 arrow
35 arrow
36 level
171 first wedge
172 second wedge
173 point of contact

1. Bin insert for binning of light emitting devices, comprising a hollow structural section further comprising:
a top opening and a bottom opening at a top and a bottom end of the hollow structural section, respectively,
a wall extending along a main axis between the top opening and the bottom opening,
parallel segments in the wall, wherein the wall in the parallel segments extends parallel with respect to the main axis, and
inclined segments in the wall, wherein the wall in the inclined segments extends under a tilted angle and towards the main axis, wherein the parallel segments and the inclined segments are arranged such as to confine an angulated falling path in the hollow structural section.

2. Bin insert according to claim 1, wherein the hollow structural section is confined by a circular, a rectangular, or a square shaped cross-section.

3. Bin insert according to claim 2, wherein the top opening and the bottom opening extend over the whole cross-section of the hollow structural section.

4. Bin insert according to claim 1, wherein the parallel segments and the inclined segments confining the angulated falling path in the hollow structural section are arranged such that the angulated falling path in the hollow structural section connects the top opening with the bottom opening of the hollow structural section.

5. Bin insert according to claim 1, comprising at least two inclined segments forming a pair of inclined segments wherein the two inclined segments of the pair are tilted with respect to each other so as to form a wedge in the wall.

6. Bin insert according to claim 5, comprising at least one further pair of inclined segments wherein the two inclined segments of the at least one further pair are tilted with respect to each other so as to form a further wedge in the wall.

7. Bin insert according to claim 6, wherein the wedge and the at least one further wedge are arranged with respect to each other such that the angulated falling path in the hollow structural section comprises a zigzag course connecting the top opening with the bottom opening of the hollow structural section.

8. Bin insert according to claim 7, further comprising a receiving portion having a top side connected to the wedge or to the at least one further wedge, and having a bottom side comprising the bottom opening of the hollow structural section.

9. Bin insert according to claim 8, wherein the bottom opening of the hollow structural section is slanted with respect to the main axis.

10. Bin insert according to claim 1, wherein the hollow structural section is made of an at least semi-transparent plastic, in particular made of semi-transparent electrostatic-sensitive devices plastic.

11. Bin insert according to claim 1, wherein the hollow structural section comprises a molded plastic.

12. Binning arrangement for binning of light emitting devices, in particular for binning of light emitting diodes, comprising:
at least one bin insert said bin insert comprising
a hollow structural section,
a top opening and a bottom opening at a top and a bottom end of the hollow structural section, respectively,
a wall extending along a main axis between the top opening and the bottom opening,
parallel segments in the wall, wherein the wall in the parallel segments extends parallel with respect to the main axis, and
inclined segments in the wall, wherein the wall in the inclined segments extends under a tilted angle and towards the main axis, wherein the parallel segments and the inclined segments are arranged such as to confine an angulated falling path in the hollow structural section, and
at least one bin for receiving the bin insert.

13. Binning arrangement according to claim 12, wherein the bin insert fits into the bin.

14. Binning arrangement according to claim 12, wherein a slanted base of the bin corresponds to the slanted bottom opening of the bin insert.

15. (canceled)
